(19) United States
(12) Patent Application Publication
(10) Pub. No.: US 2026/0066870 A1
(43) Pub. Date: Mar. 5, 2026

(54) MEMS RESONATOR

(71) Applicant: ROHM CO., LTD., Kyoto (JP)

(72) Inventors: Toma FUJITA, Kyoto (JP); Martin Wilfried HELLER, Kyoto (JP); Daisuke NISHINOHARA, Kyoto (JP); Hideaki HASHIMOTO, Kyoto (JP); Xingwei WANG, Fukuoka (JP); Tamio IKEHASHI, Fukuoka (JP)

(73) Assignee: ROHM CO., LTD., Kyoto (JP)

(21) Appl. No.: 19/312,847

(22) Filed: Aug. 28, 2025

(30) Foreign Application Priority Data
Aug. 29, 2024 (JP) 2024-147911

(51) Int. Cl. H03H 9/02; H03H 9/24

(52) U.S. Cl. CPC H03H 9/02275; H03H 9/02433; H03H 9/2431; H03H 2009/02291

(57) ABSTRACT

A MEMS resonator includes a pantograph that is a parallelogram, an oscillator connected to each vertex of the pantograph, and an electrode disposed opposite each oscillator, and forming a capacitor with the oscillator. A set of the electrodes disposed opposite to a set of the oscillators along an extension direction of a diagonal line of the pantograph that is the parallelogram have applied thereto a voltage differing in phase by 180° from another set of the electrodes disposed opposite to another set of the oscillators along an extension direction of another diagonal line of the pantograph. At least two of the MEMS resonators are connected so as to share one oscillator.

### CROSS REFERENCE TO RELATED APPLICATION

This application is based upon and claims the benefit of priority of the prior Japanese Patent Application No. 2024-147911, filed on Aug. 29, 2024, the entire contents of which are incorporated herein by reference.

### TECHNICAL FIELD

The present disclosure relates to a MEMS resonator, and in particular, relates to a MEMS resonator that can be miniaturized and have increased efficiency.

### BACKGROUND ART

In recent years, MEMS resonators, which are highly reliable and can be miniaturized have been put to practical use as a substitute for conventional crystal oscillators. An example of a MEMS resonator has a structure including beams formed in a cross extending in four directions from connection points, and a ring-shaped oscillator at the end of each beam, the entire MEMS resonator oscillating at a prescribed resonant frequency as a result of the oscillators repeatedly expanding and contracting simultaneously.

### BRIEF DESCRIPTION OF THE DRAWINGS

FIG. 1 is a plan view of a MEMS resonator according to Embodiment 1 of the present disclosure.

FIG. 2 is a cross-sectional view along the line IIA-IIB of FIG. 1.

FIG. 3 shows drive voltages of the MEMS resonator according to Embodiment 1 of the present disclosure.

FIG. 4 is a plan view for explaining the operation of the MEMS resonator according to Embodiment 1 of the present disclosure.

FIG. 5 is a plan view of a MEMS resonator according to Embodiment 2 of the present disclosure.

FIG. 6 is a cross-sectional view along the line VIA-VIB of FIG. 5.

FIG. 7 is a plan view of a MEMS resonator according to Embodiment 3 of the present disclosure.

FIG. 8 is a plan view of a MEMS resonator according to Embodiment 4 of the present disclosure.

FIG. 9 is a plan view of a MEMS resonator according to Embodiment 5 of the present disclosure.

FIG. 10 is a plan view of a MEMS resonator according to Embodiment 6 of the present disclosure.

FIG. 11 is a plan view showing an example of an application of a MEMS resonator according to Embodiment 7 of the present disclosure.

FIG. 12 is a plan view of a MEMS resonator according to Embodiment 8 of the present disclosure.

FIG. 13 is a modification example of a pantograph of the MEMS resonator according to Embodiments 1 to 8 of the present disclosure.

### DETAILED DESCRIPTION OF EMBODIMENTS

### Embodiment 1

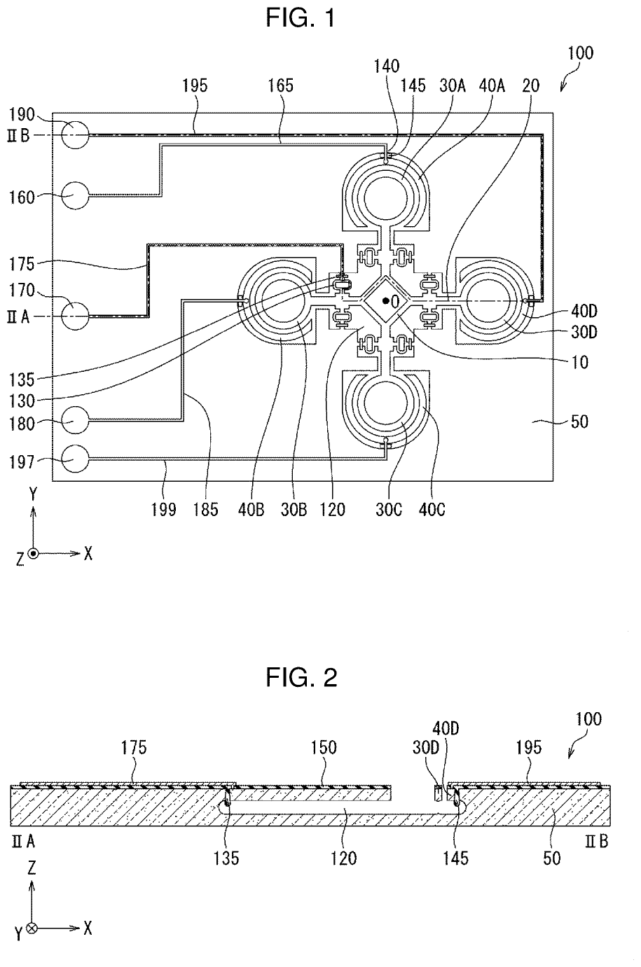

FIG. 1 is a plan view of a MEMS resonator according to Embodiment 1 of the present disclosure, the entirety of which is represented by the reference character 100, and FIG. 2 is a cross-sectional view along the line IIA-IIB of FIG. 1.

The MEMS resonator 100 includes a square pantograph 10. At each of the four vertices of the pantograph 10, beams 20 are provided along the extension direction of each diagonal line of the square, and ring-shaped oscillators 30A to 30D are connected to the end of each beam 20. Additionally, arc-shaped external electrodes 40A to 40D are provided at the periphery of the oscillators 30A to 30D so as to surround each of the oscillators 30A to 30D at a fixed distance therefrom. The oscillators 30A to 30D and the external electrodes 40A to 40D form capacitors.

The beams 20, the oscillators 30A to 30D, and the external electrodes 40A to 40D are disposed at positions at 4-fold rotational symmetry about a central axis O formed along the Z axis direction of the square pantograph 10. In other words, the oscillators 30A to 30D are connected equidistantly from each vertex of the square by the beams 20 disposed in the extension directions of the diagonal lines of the square. The pantograph 10, the beams 20, the oscillators 30A to 30D, and the external electrodes 40A to 40D are formed by etching a substrate 50 made of silicon, for example.

A recess 120 is formed in the substrate 50, and the pantograph 10, the beams 20, and the oscillators 30A to 30D are suspended by an anchor 130 over the recess 120, and the external electrodes 40A to 40D are suspended by an anchor 140 over the recess 120. Insulating isolation joints (IJ) 135 and 145 made of silicon oxide, for example, are respectively inserted in the middle of the anchors 130 and 140, and electrically insulate the substrate 50 from the pantograph 10, the beams 20, and the oscillators 30A to 30D as well as electrically insulating the substrate 50 from the external electrodes 40A to 40D.

As shown in FIG. 2, the surface of the substrate 50 is covered by a surface oxide film 150 made of silicon oxide, for example. Electrodes 160, 170, 180, 190, and 197 are provided on the surface oxide film 150. The electrode 160 is connected to the external electrode 40A by a wiring layer 165. The electrode 170 is connected to the pantograph 10, the beams 20, and the oscillators 30A to 30D by a wiring layer 175. The electrode 180 is connected to the external electrode 40B by a wiring layer 185. The electrode 190 is connected to the external electrode 40D by a wiring layer 195. The electrode 197 is connected to the external electrode 40C by a wiring layer 199. The electrodes 160, 170, 180, 190, and 197 and the wiring layers 165, 175, 185, 195, and 199 are made of copper, for example. In FIG. 1, the surface oxide film 150 is omitted.

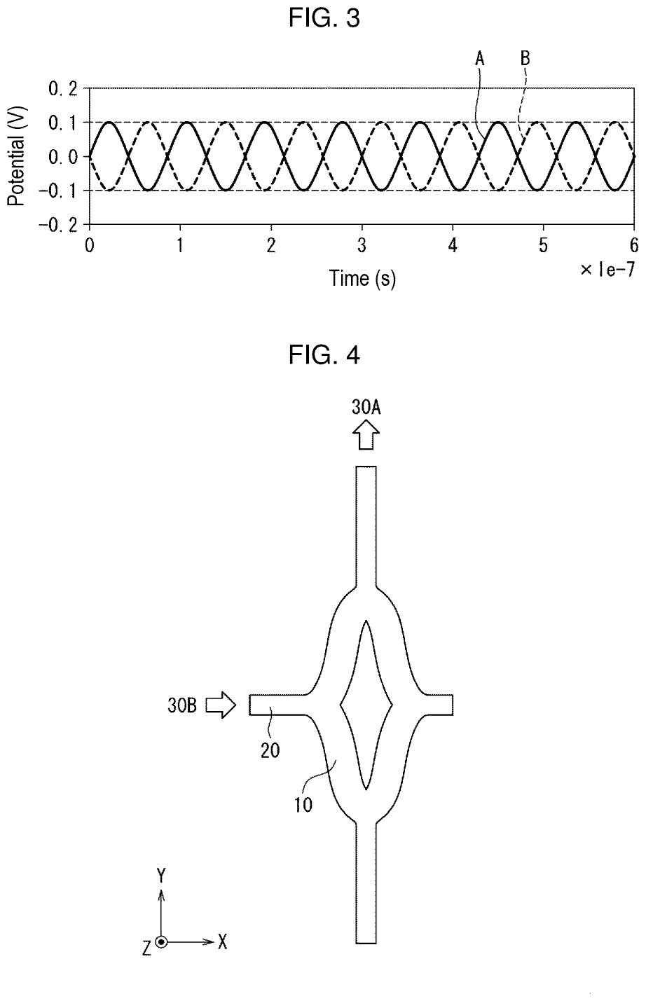

Next, the operation of the MEMS resonator 100 shown in FIG. 1 will be described with reference to FIGS. 3 and 4. FIG. 3 shows voltages applied from the electrodes 160 and 180 of the MEMS resonator 100 of FIG. 1 to the external electrodes 40A and 40B; A is a voltage applied to the external electrode 40A and B is a voltage applied to the external electrode 40B. A constant voltage of 18V is applied from the electrode 170 to the pantograph 10, the beams 20, and the oscillators 30A to 30D. The electrodes 190 and 197 are used as detection electrodes.

As shown in FIG. 3, the external electrodes 40A and 40B, which are adjacent to each other and at 90° to each other, have applied thereto alternating current voltages at opposite phases to each other within a range of ±0.1V centered on 0V. As a result, in a state where the oscillator 30B is fixed at 18V, +0.1V is applied to the external electrode 40A, and −0.1V is applied to the external electrode 40B, for example, a large electrostatic attractive force is generated by the capacitor formed by the external electrode 40B and the oscillator 30B, causing the oscillator 30B to be pulled towards the external electrode 40B. As a result, the pantograph 10 contracts in the X direction and is stretched in the Y direction via the beams 20, thereby causing the contraction of 30A and 30C.

FIG. 4 shows the deformation of the pantograph 10 in this state; due to the oscillator 30B, the pantograph 10 is pressed in the 30B direction and deformed. As a result, the oscillator 30A is pressed outward in the 30A direction via the beam 20. When the applied voltage inverts, the oscillator 30A is pulled by the external electrode 40A, and the pantograph 10 deforms accordingly.

Thus, as a result of voltages of opposite phases being applied to the adjacent external electrodes 40A and 40B, the oscillators 30A and 30B can be caused to oscillate at a prescribed resonant frequency. In FIG. 3, sine waves were used, but other types of waveforms such as square waves or triangle waves may be used (same applies to the embodiments below).

In particular, as a result of the pantograph 10 deforming, deformation of the beams 20 as had occurred in conventional configurations is mitigated, thereby preventing energy consumption due to the deformation of the beams 20.

Here, a case in which voltages at reverse phases to each other were applied to the adjacent external electrodes 40A and 40B was described, but a configuration in which voltages at reverse phases to each other are applied to the external electrodes 40A and 40C and to the external electrodes 40B and 40D may be used (where the external electrodes 40A and 40C are at the same potential as each other, and the external electrodes 40B and 40D are at the same potential as each other).

In FIG. 1 if the electrodes 190 and 197 are used as detection electrodes, a differential amplifier is connected via capacitance-voltage (C/V) conversion circuits connected respectively to the electrodes 190 and 197, thereby detecting signals, for example. In the MEMS resonator 100, as described above, an alternating current voltage for oscillating the oscillator 30A is applied to the electrode 160. As a result, a change in capacitance resulting from the oscillation of the oscillator 30C is inputted to one input terminal of the differential amplifier via the capacitance-voltage (C/V) conversion circuit connected to the electrode 197 (not shown). Meanwhile, a change in capacitance resulting from the oscillation of the oscillator 30D is inputted to another input terminal of the differential amplifier via the capacitance-voltage (C/V) conversion circuit connected to the electrode 190 (not shown).

Here, a portion of the alternating current voltage is superimposed on the electrode 197 by a parasitic capacitance C1 between the electrode 160 and the electrode 197. This phenomenon is referred to as “feedthrough,” which causes changes in capacitance due to oscillation of the oscillator 30C to be less apparent. Similarly, feedthrough also occurs due to a parasitic capacitance C2 between the electrode 160 and the electrode 190, causing a portion of the alternating current voltage to be superimposed on the electrode 190, thereby making the changes in capacitance due to oscillation of the oscillator 30D less apparent.

In the MEMS resonator 100 according to Embodiment 1 of the present disclosure, the oscillator 30C and the oscillator 30D oscillate at opposite phases to each other, whereas the two feedthroughs are superimposed on the electrodes 197 and 190 at the same phase. Thus, at the output unit of the differential amplifier, signals resulting from the oscillation of the oscillators 30C and 30D are amplified, while the feedthrough signals are canceled out and therefore reduced. In particular, when C1=C2, the feedthrough signals are completely canceled out.

Thus, in the MEMS resonator 100 according to Embodiment 1 of the present disclosure, the occurrence of feedthrough can be mitigated and the detection sensitivity can be improved through the use of the pantograph 10. Here, for ease of explanation, the application of the alternating current voltage to the oscillator 30B was ignored, but feedthrough is similarly canceled out for input signals to the oscillator 30B.

### Embodiment 2

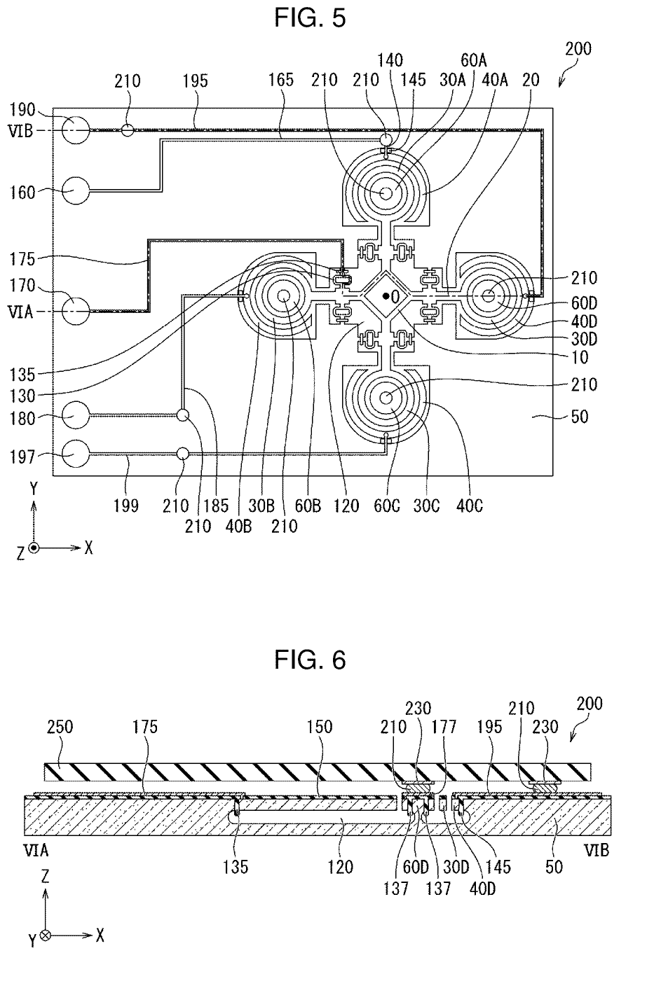

FIG. 5 is a plan view of a MEMS resonator according to Embodiment 2 of the present disclosure, the entirety of which is represented by the reference character 200, and FIG. 6 is a cross-sectional view along the line VIA-VIB of FIG. 1. In FIGS. 5 and 6, the same reference characters as those of FIGS. 1 and 2 indicate the same or corresponding units. In FIG. 5, a lid 250 is omitted in order to facilitate understanding of the structure.

In the MEMS resonator 200 according to Embodiment 2, circular internal electrodes 60A to 60D are further provided to the inside of the ring-shaped oscillators 30A to 30D. Bumps 210 for connecting to a wiring layer 230 of the lid 250 (see FIG. 6) are provided over the internal electrodes 60A to 60D and the wiring layers 165, 185, 195, and 199. The bumps 210 are made of Au—Au, AlGe, Cu—Cu, or AuSn, for example. Other structures and operations are similar to those of the MEMS resonator 100.

Similar to the MEMS resonator 100, in the MEMS resonator 200, voltages at opposite phases to each other are applied to adjacent external electrodes among the external electrodes 40A to 40D, and voltages at opposite phases are also applied between the external electrodes 40A to 40D and the internal electrodes 60A to 60D.

Specifically, the voltage A of FIG. 3 is applied to the external electrodes 40B and 40D and the internal electrodes 60A and 60C, and the voltage B of FIG. 3, which is at the opposite phase thereto, is applied to the external electrodes 40A and 40C and the internal electrodes 60B and 60D.

As shown in FIG. 6, the internal electrodes 60A to 60D are formed as structures connected to the bottom surface of the recess 120 during the step of etching the recess 120 of the substrate 50. The internal electrode 60A is insulated from the substrate 50 by a ring-shaped isolation joint (IJ) 137, is connected to the wiring layer 230 of the lid 250 via the wiring layer 177 and the bump 210, and has applied thereto a prescribed voltage. This similarly applies to the other internal electrodes 60B and the like.

Thus, by providing the internal electrodes 60A to 60D in addition to the external electrodes 40A to 40D, the oscillators 30A to 30D can be caused to oscillate more efficiently.

Here, the internal electrodes 60A to 60D are circular, but may alternatively be ring-shaped. Also, the internal electrodes 60A to 60D were isolated from the substrate 50 by the isolation joint (IJ) 137, but a configuration may be adopted in which an SOI substrate is used for the substrate 50, and the internal electrodes 60A to 60D are insulated from the substrate by the insulator of the SOI substrate.

### Embodiment 3

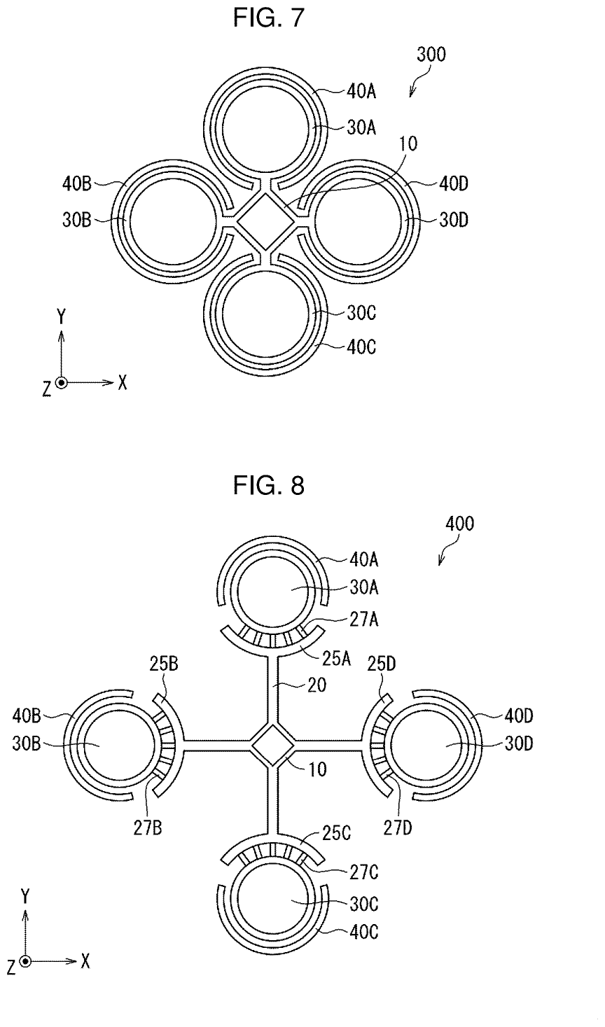

FIG. 7 is a plan view of a MEMS resonator according to Embodiment 3 of the present disclosure, the entirety of which is represented by the reference character 300. In FIG. 7, the same reference characters as those of FIGS. 1 and 2 indicate the same or corresponding units, and the substrate 50, the recess 120, the anchors 130 and 140, and the like are omitted.

In the MEMS resonator 300 according to Embodiment 3, the oscillators 30A to 30D are directly connected to the four vertices of the pantograph 10 without the use of beams therebetween. Other structures or operations are the same as those of the MEMS resonator 100.

In the MEMS resonator 300 according to Embodiment 3, there is no restriction that the length of the beams be an integer multiple of half the resonance wavelength, unlike conventional MEMS resonators, and thus, the beams can be omitted as shown in FIG. 7.

Thus, the oscillators 30A to 30D are directly connected to the pantograph 10, which allows for improved oscillation efficiency and a size reduction for the resonator.

### Embodiment 4

FIG. 8 is a plan view of a MEMS resonator according to Embodiment 4 of the present disclosure, the entirety of which is represented by the reference character 400. In FIG. 8, the same reference characters as those of FIGS. 1 and 2 indicate the same or corresponding units, and the substrate 50, the recess 120, the anchors 130 and 140, and the like are omitted.

In the MEMS resonator 400 according to Embodiment 4, arc-shaped beam expansion units 25A to 25D are provided along the oscillators 30A to 30D at the end of the beams extending from the four vertices of the pantograph 10. Additionally, the beam expansion units 25A to 25D and the oscillators 30A to 30D are connected to each other by a plurality of connection units 27A to 27D. It is preferable that the gap between the oscillators 30A to 30D and the beam expansion units 25A to 25D be constant.

The beam expansion units 25A to 25D and the connection units 27A to 27D are formed by etching the substrate 50, similar to the formation of the pantograph 10 and the like, and are suspended above the recess 120. Other structures or operations are the same as those of the MEMS resonator 100.

Thus, by providing the beam expansion units 25A to 25D and the connection units 27A to 27D, when the oscillators 30A to 30D contract, for example, the oscillators 30A to 30D are less susceptible to deforming due to the oscillators 30A to 30D being connected to the beam expansion units 25A to 25D via the plurality of connection units 27A to 27D. As a result, the contraction of the oscillators 30A to 30D results in translational motion to pull the beams 20, causing the oscillation to be efficiently transmitted to the pantograph 10.

In FIG. 8, five connection units 27A to 27D are provided for each beam expansion unit 25A to 25D, but as long as the oscillators 30A to 30D are connected at a plurality of positions to the beam expansion units 25A to 25D, the number of connection units is not limited to five. It is preferable that the plurality of connection units 27A to 27D be provided equidistantly between the oscillators 30A to 30D and the beam expansion units 25A to 25D.

### Embodiment 5

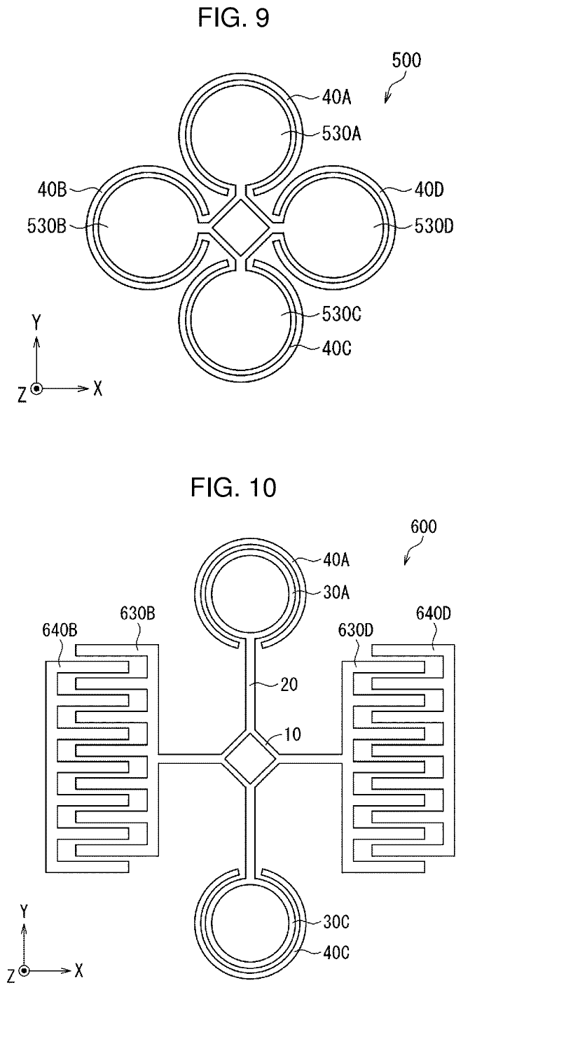

FIG. 9 is a plan view of a MEMS resonator according to Embodiment 5 of the present disclosure, the entirety of which is represented by the reference character 500. In FIG. 9, the same reference characters as those of FIG. 7 indicate the same or corresponding units, and the substrate 50, the recess 120, the anchors 130 and 140, and the like are omitted.

In the MEMS resonator 500 according to Embodiment 5, oscillators 530A to 530D are directly connected to the four vertices of the pantograph 10 without the use of beams therebetween, and the oscillators 530A to 530D have a circular shape rather than a ring shape. Other structures or operations are the same as those of the MEMS resonator 300 shown in FIG. 7.

Such oscillators 530A to 530D can be formed as structures connected to the bottom surface of the recess 120, similar to the internal electrodes 60A to 60D of FIG. 5, and in this structure, the anchors 130 that hold the oscillators 530A to 530D and the pantograph 10 can be omitted.

### Embodiment 6

FIG. 10 is a plan view of a MEMS resonator according to Embodiment 6 of the present disclosure, the entirety of which is represented by the reference character 600. In FIG. 10, the same reference characters as those of FIG. 1 indicate the same or corresponding units, and the substrate 50, the recess 120, the anchors 130 and 140, and the like are omitted.

The MEMS resonator 600 according to Embodiment 5 uses oscillators 630B and 630D and external electrodes 640B and 640D, which are comb-shaped and oppose each other, instead of the oscillators 30B and 30D and the external electrodes 40B and 40D of the MEMS resonator 100 of Embodiment 1. In other words, the parallelly arranged comb-shaped external electrode 640B and the parallelly arranged comb-shaped oscillator 630B, disposed so as to interdigitate therewith, together form a capacitor (the external electrode 640D and the oscillator 630D form the same structure). The comb-shaped oscillators 630B and 630D and external electrodes 640B and 640D are supported in a suspended state over the recess 120 formed in the substrate 50. Other structures or operations are the same as those of the MEMS resonator 100 shown in FIG. 1.

In the MEMS resonator 600, voltages at opposite phases are applied respectively to the external electrodes 40A and 40C and the external electrodes 640B and 640D within a range of ±0.1V centered on 18V. As a result, in a state where +0.1V is applied to the external electrodes 40A and 40C and −0.1v is applied to the external electrodes 640B and 640D, for example, a large electrostatic attractive force is generated by the comb-shaped capacitors formed between the external electrode 640B and the oscillator 630B and between the external electrode 640D and the oscillator 630D, causing the oscillators 630B and 630D to be pulled towards the external electrodes 640B and 640D. As a result, the pantograph 10 is also pulled via the beams 20.

Additionally, the oscillators 30A and 30C are pulled inward via the beams 20.

Thus, it is possible to form a MEMS resonator using capacitors formed from comb-shaped external electrodes and oscillators. In FIG. 10, two of the capacitors have a comb-shaped structure, but alternatively, all of the capacitors may have a comb-shaped structure.

### Embodiment 7

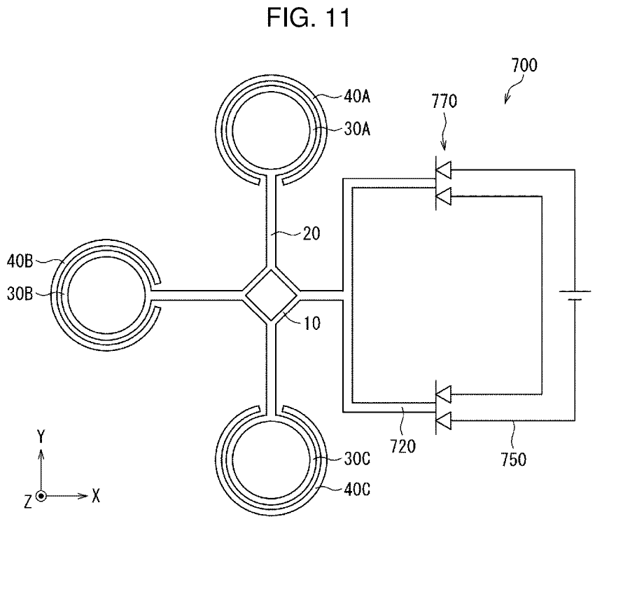

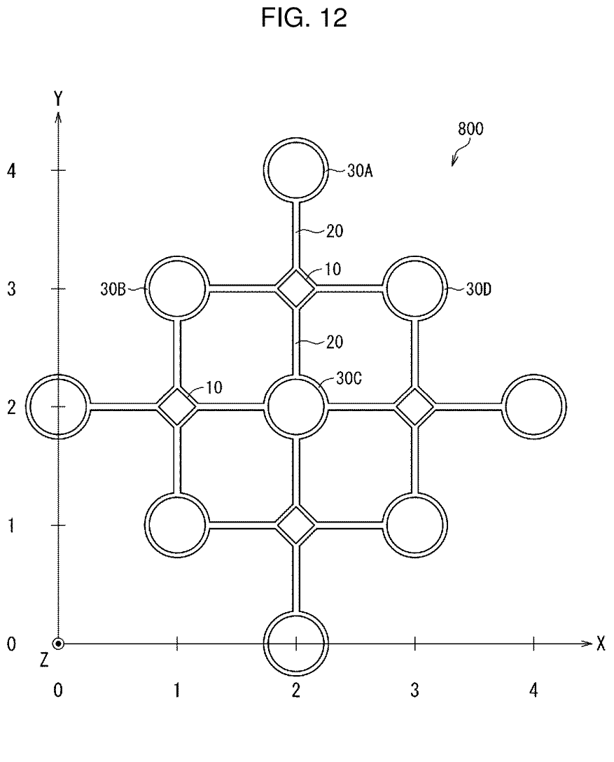

FIG. 11 is a plan view showing an example of an application of a MEMS resonator according to Embodiment 7 of the present disclosure, the entirety of which is represented by the reference character 700. In FIG. 11, the same reference characters as those of FIG. 1 indicate the same or corresponding units, and the substrate 50, the recess 120, the anchors 130 and 140, and the like are omitted.

The MEMS resonator 700 according to Embodiment 7 has a configuration where the MEMS resonator 100 of FIG. 1 additionally has beams 720 that branch off from a beam 20, and a direct current voltage circuit 750 provided with switching units 770. The beams 720 and the switching units 770 can be formed by etching the substrate 50. The beams 720 are formed so as to be suspended in continuation from the beam 20, for example, and the switching units 770 are formed from suspended opposing electrodes, for example.

Similar to the MEMS resonator 100, as a result of voltages of opposite phases being applied to the adjacent external electrodes 40A and 40B, the oscillator 30A repeatedly expands and contracts. When the oscillator 30A expands and the oscillator 30B contracts, the pantograph 10 deforms in the manner of FIG. 4, causing the switching units 770 to be set to the ON state (e.g., by causing the opposing electrodes to come into contact with each other). Conversely, when the oscillator 30A contracts and the oscillator 30B expands, the pantograph 10 deforms so as to be pulled towards the oscillator 30A, causing the switching units 770 to be set to the OFF state (e.g., by causing the opposing electrodes to separate from each other).

By using the MEMS resonator 700, it is possible to set the voltage of the direct current voltage circuit 750 to ON/OFF in synchronization with the oscillation frequency of the oscillators, and to convert the direct current voltage to an alternating current voltage at a prescribed frequency.

### Embodiment 8

FIG. 12 is a plan view showing an example of an application of a MEMS resonator according to Embodiment 8 of the present disclosure, the entirety of which is represented by the reference character 800. The MEMS resonator 800 is formed by connecting MEMS resonators 100 according to Embodiment 1, for example, to form a collective MEMS resonator (MEMS resonator connection structure) 800.

Specifically, as shown in FIG. 12, the MEMS resonators 100 are connected in the X axis direction and the Y axis direction such that adjacent MEMS resonators 100 share an oscillator. In FIG. 12, the external electrodes, the anchors, and the like are omitted.

In the MEMS resonator 800 of FIG. 12, oscillators at coordinates (2, 0), (0, 2), (4, 2), and (2,4) have applied thereto a voltage at the opposite phase to oscillators at coordinates (1, 1), (3, 1), (1,3), and (3, 3). If, for example, the former oscillators expand while the latter oscillators contract, then all of the pantographs deform so as to be pulled in the X axis direction as shown in FIG. 3. If the applied voltage is inverted by 180°, then the pantographs are deformed so as to be pulled in the Y axis direction. By alternately expanding and contracting the former and latter oscillators, it is possible to cause the MEMS resonator 800 to oscillate at a given oscillation frequency.

In the MEMS resonator 800 according to Embodiment 8, by connecting a plurality of MEMS resonators and causing resonance therein, a larger resonance signal can be attained. In particular, there is no limit on the length of the beams connecting the oscillators to the pantographs, and thus, the MEMS resonator 800 can be reduced in size. Alternatively, it is similarly possible to connect the MEMS resonators 200, 300, 400, 500, or 600 of the other embodiments to each other.

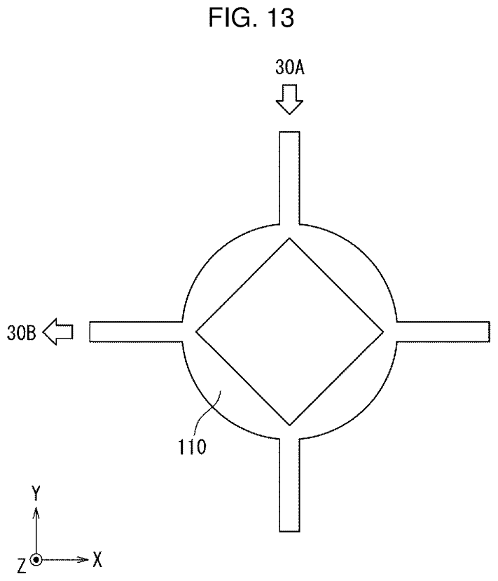

The embodiments of the present disclosure describe a square pantograph, but the shape of the pantograph may be a rhombus, a rectangle, or a parallelogram. If the pantograph takes on any of the aforementioned shapes, it is preferable that the oscillators be disposed at positions at equal distance from the respective vertices along the extension of the diagonal lines. The essence of the shape of the pantograph is that the pantograph deforms along two axial directions at opposite phases as shown in FIG. 4. As long as this condition is satisfied, then the shape may be non-quadrilateral 110 with a uniform thickness as shown in FIG. 13, for example.

In the embodiments of the present disclosure, examples were described in which capacitors constituted of the oscillators 30A to 30D and the external electrodes 40A to 40D are used for driving the MEMS resonator, but some of the capacitors may be used for detecting the resonant frequency. Furthermore, the same capacitors can be switched periodically, for example, to be used for both driving and detection alternately.

### <Notes>

The present disclosure is a MEMS resonator including:
a pantograph that is a parallelogram;
an oscillator connected to each vertex of the pantograph; and
an electrode disposed opposite each oscillator, and forming a capacitor with the oscillator.

In this MEMS resonator, as a result of the pantograph deforming, it is possible to prevent energy consumption resulting from deformation of the beams as had occurred in conventional configurations, and to attain efficient resonation. Also, unlike conventional structures, there is no limit on the length of the beams, and thus, the MEMS resonator can be reduced in size.

The present disclosure is the MEMS resonator, wherein a set of said electrodes disposed opposite to a set of said oscillators along an extension direction of a diagonal line of the pantograph that is the parallelogram have applied thereto a voltage differing in phase by 180° from another set of said electrodes disposed opposite to another set of said oscillators along an extension direction of another diagonal line of the pantograph.

In this manner, by applying voltages at opposite phases to electrodes opposing adjacent oscillators, it is possible to cause the adjacent oscillators to alternately expand and contract, thereby allowing for resonation at a high efficiency.

In the present disclosure, it is preferable that the parallelogram be a square or a rectangle. Forming the pantograph into a square or rectangular shape increases ease of manufacturing and arrangement thereof.

In the present disclosure, the pantograph and the oscillators are connected to each other by beams disposed along extension directions of diagonal lines of the parallelogram. In this case, there is no restriction that the length of the beams be an integer multiple of half the resonance wavelength, unlike with conventional structures.

The present disclosure is also the MEMS resonator wherein ends of the beams include beam expansion units along the oscillators, and the beam expansion units are connected to the oscillators by a plurality of connection units. According to this structure, the contraction of the oscillators results in translational motion to pull the beams, causing the oscillation to be efficiently transmitted to the pantograph.

In the present disclosure, the pantograph and the oscillators may be directly connected to each other. According to this structure, oscillation of the oscillators can be efficiently transmitted to the pantograph.

In the present disclosure, the electrodes may be arc-shaped external electrodes provided outside of the oscillators.

In the present disclosure, the electrodes may be circular internal electrodes provided inward of the oscillators.

In the present disclosure, the capacitors may be constituted of ring-shaped oscillators and arc-shaped electrodes.

In the present disclosure, the capacitors may be constituted of comb-shaped said oscillators and comb-shaped said electrodes disposed opposite to each other.

The present disclosure may be a MEMS resonator further including: a switching unit connected to one vertex of the pantograph; and a direct current voltage circuit connected to the switching unit, wherein by oscillating the oscillators, the switching unit is turned ON or OFF. In this MEMS resonator, it is possible to set the voltage of the direct current voltage circuit to ON/OFF in synchronization with the oscillation frequency of the oscillators, and to convert the direct current voltage to an alternating current voltage at a prescribed frequency.

The present disclosure is also a MEMS resonator connection structure wherein least two of the above-mentioned MEMS resonators are connected so as to share one oscillator. By connecting a plurality of MEMS resonators and causing resonance therein, a larger resonance signal can be attained.

### INDUSTRIAL APPLICABILITY

The MEMS resonator according to the present disclosure can be applied to resonators, filters, temperature sensors, pressure sensors, mass sensors, and the like.

What is claimed is:

1. A MEMS resonator, comprising:
a pantograph that is a parallelogram having vertexes;
oscillators connected respectively to the vertexes of the pantograph; and
electrodes respectively disposed opposite the oscillators, and forming capacitors with the oscillators.

2. The MEMS resonator according to claim 1,
wherein a set of said electrodes disposed opposite to a set of said oscillators along an extension direction of a diagonal line of the pantograph that is the parallelogram have applied thereto a voltage differing in phase by 180° from another set of said electrodes disposed opposite to another set of said oscillators along an extension direction of another diagonal line of the pantograph.

3. The MEMS resonator according to claim 1, wherein the parallelogram is a square or a rectangle.

4. The MEMS resonator according to claim 1,
wherein the pantograph and the oscillators are connected to each other by beams disposed along extension directions of diagonal lines of the parallelogram.

5. The MEMS resonator according to claim 4,
wherein ends of the beams include beam expansion units along the oscillators, and the beam expansion units are connected to the oscillators by a plurality of connection units.

6. The MEMS resonator according to claim 1,
wherein the pantograph and the oscillators are directly connected to each other.

7. The MEMS resonator according to claim 1,
wherein the electrodes are arc-shaped external electrodes provided outside of the oscillators.

8. The MEMS resonator according to claim 1,
wherein the electrodes are circular internal electrodes provided inward of the oscillators.

9. The MEMS resonator according to claim 1,
wherein said oscillators are ring-shaped and said electrodes are arc-shaped.

10. The MEMS resonator according to claim 1,
wherein said oscillators are comb-shaped and said electrodes are comb-shaped.

11. The MEMS resonator according to claim 1, further comprising:
a switching unit connected to one vertex of the pantograph; and
a direct current voltage circuit connected to the switching unit,
wherein by oscillating the oscillators, the switching unit is turned ON or OFF.

12. A MEMS resonator connection structure,
wherein at least two of MEMS resonators according to claim 1 are connected so as to share one of said oscillators.
